(19) United States
(12) Patent Application Publication
(10) Pub. No.: US 2014/0008113 A1
(43) Pub. Date: Jan. 9, 2014

(54) TRANSPARENT ELECTRODE FILM HAVING CONDUCTIVE POLYMER ELECTRODE LAYER

(71) Applicants: Kwang Suck Suh, Seongnam-si (KR); Jong Eun Kim, Yangchun-gu (KR); Tae Young Kim, Songpa-gu (KR)

(72) Inventors: Kwang Suck Suh, Seongnam-si (KR); Jong Eun Kim, Yangchun-gu (KR); Tae Young Kim, Songpa-gu (KR)

(21) Appl. No.: 14/005,929

(22) PCT Filed: Mar. 19, 2012
(86) PCT No.: PCT/KR12/01966

§ 371 Date: Sep. 18, 2013

(30) Foreign Application Priority Data
Mar. 18, 2011 (KR) 10-2011-0024299

(51) Int. Cl. H05K 1/02

(52) U.S. Cl. CPC H05K 1/0274
USPC 174/257

(57) ABSTRACT

This invention relates to a transparent electrode film for a touch screen panel using poly(3,4-ethylenedioxythiophene) (PEDOT) that is a kind of conductive polymer, and more particularly to a technique of manufacturing a transparent electrode film by forming a PEDOT coating on the surface of a transparent substrate such as polyester wherein a photocurable resin layer is formed on both surfaces of the substrate film to reduce changes in surface resistance upon aging testing, and an electrode layer containing PEDOT as an effective component is formed on the photocurable resin layer formed on one surface thereof.

### TECHNICAL FIELD

The present invention relates to a transparent electrode film for a touch screen panel, which includes a transparent electrode layer formed by applying a composition containing, as an effective component, poly(3,4-ethylenedioxythiophene) (PEDOT) that is a conductive polymer on the surface of a transparent substrate film such as polyester. Particularly, this invention relates to a technique which enables changes in surface resistance to be less than 10% compared to an initial resistance value even when the transparent electrode film having the electrode layer containing PEDOT as the effective component is subjected to aging under conditions of a temperature equal to or higher than the glass transition temperature of the substrate film and a high relative humidity.

### BACKGROUND ART

Recently, touch screen panels which may be operated when touched by a hand of a user are increasingly adopted in, for example, smart phones and tablet PCs. Because of operational convenience, such panels are widely used not only in small electronic devices such as smart phones, but also in large displays such as monitors, TV sets, etc.

The principal part of these touch screen panels is a transparent electrode layer or a transparent electrode film which is able to recognize the touch by a hand or the other tools. This transparent electrode film is formed by applying indium tin oxide (ITO) having high electrical conductivity to a thickness of at least tens of nanometers on the surface of a transparent substrate film such as polyester using sputtering. Because the ITO film has high electrical conductivity and high light transmittance, it is employed in almost all of the transparent electrode films for touch screen panels which are currently available.

However, because the ITO film results from thinly forming a metal oxide in which a mechanical property, namely brittleness, is very high on the surface of a flexible polymer substrate material, the surface ITO layer may be cracked when a thermal impact is applied thereto, making it impossible to function as an electrode layer. Particularly where high heat and humidity are applied as in an aging test that is performed under conditions of a temperature equal to or higher than the glass transition temperature of the substrate film and a high humidity (e.g., where the substrate film is PET, it is allowed to stand at 85° C. and a relative humidity of 85% for 120 hr; 85° C./85% RH/120 hr test), there may occur a difference in thermal expansion or thermal shrinkage between the substrate film and the ITO layer, and thus the surface metal oxide layer is mechanically damaged, undesirably frequently causing crack defects. Also the electrode layer which is a metal oxide having high brittleness is problematic because cracks may occur on the surface metal oxide layer upon applying a predetermined force to write letters, and thus the written letters cannot be recognized.

### DISCLOSURE

### Technical Problem

With the goal of solving the above problems, the use of a conductive polymer is possible. Because the conductive polymer is an organic material, it is highly bondable with a substrate film which is an organic material, so that cracks may be prevented from occurring on the surface electrode layer even after an aging test is performed in the presence of heat.

Accordingly, a technique that prevents the surface resistance value of the electrode layer composed of a conductive polymer from greatly changing even when aging is performed at a temperature equal to or higher than the glass transition temperature of the substrate film and a high relative humidity as mentioned above, and a transparent electrode film containing PEDOT as an effective component manufactured thereby, are required.

An object of the present invention is to provide a transparent electrode film using an electrode layer containing PEDOT as an effective component, wherein even when aging is performed for about 120 hr under conditions of a temperature equal to or higher than the glass transition temperature of a substrate and a high relative humidity, for example, of 85° C./85% RH of a polyester film, changes in surface resistance of the electrode layer are less than 10% compared to an initial resistance value.

The technical problem of the present invention is not limited to the above, and the other technical problems which are not mentioned will be definitely understood to those skilled in the art from the following description.

### Technical Solution

When a conductive polymer which typically shows a predetermined color is thinly applied on the surface of a substrate film, light transmittance may increase, and thus its use as a transparent electrode film is possible. For example, poly(3,4-ethylenedioxythiophene (PEDOT) is a conductive polymer having bulk conductivity of 500˜1,000 S/cm, and a composition containing such a polymer as an effective component is prepared and then applied on the surface of a transparent substrate film such as polyester thus forming a transparent electrode film.

However, this film is known to have changes in surface resistance of 10% or more compared to an initial resistance value after so-called 85° C./85% RH/120 hr testing comprising aging at 85° C. and a relative humidity of 85% for 120 hr, drying for a predetermined period of time and measuring the changes in surface resistance. The aging temperature 85° C. is higher than the glass transition temperature of the polyester film that is the substrate film, and thus when the film is allowed to stand at this temperature for a long period of time, dimensions of the polyester film that is the substrate film may change or oligomers or the like may transfer from the inside of the material onto the surface thereof, undesirably damaging the surface electrode layer and also changing the surface resistance of the electrode layer.

As is apparent from test results of the present invention which will be described later, when a touch cell, manufactured by applying a binder such as an ester, a urethane, an acryl or the like to a thickness of one of micrometers on the surface of a substrate film to prevent such dimensional deformation and transfer of oligomers and then providing a transparent film comprising an electrode layer containing PEDOT as an effective component thereon, is allowed to stand at 85° C. and 85% RH for 120 hr, changes in surface resistance thereof are observed to be 10% or more compared to the initial resistance value. Such changes after aging are also observed to further increase in proportion to a decrease in the initial surface resistance value. This is considered to be because the thermosetting binder layer, so-called a primer forming material, formed between the substrate film and the electrode layer does not effectively prevent the dimensional deformation and the transfer of oligomers at a temperature higher than the glass transition temperature.

In the case of the polyester film, there are needs for a technique which enables the changes in surface resistance of an electrode layer composed of PEDOT to be less than 10% compared to the initial resistance value even after aging under conditions of 85° C. which is higher than the glass transition temperature of the polyester film and 85% RH for 120 hr, and for a transparent electrode film using an electrode layer containing PEDOT manufactured thereby.

When the transparent electrode film is manufactured by forming the electrode layer containing PEDOT as an effective component on the surface of the transparent substrate such as polyester, it approximately has a surface resistance of hundreds of ohms/area which is suitable for use as a transparent electrode film of a touch screen panel in terms of conductivity or surface resistance.

However, where this film is subjected to aging at a high temperature, in particular, a temperature equal to or higher than the glass transition temperature of a substrate film (e.g., in the case of a polyester film having a glass transition temperature of less than 80° C., the aging temperature is 85° C.) and a high relative humidity of about 85% for about 120 hr, the surface resistance may be increased considerably, and may be increased by a maximum of about 50%, on occasion. Such change is regarded as very large, and upon aging under the same conditions, changes in surface resistance should be less than a maximum of 10% in order to achieve end uses for electronic devices such as smart phones.

The present inventors thought that the reason why surface resistance is changed after aging is not that an electrode layer material, namely, PEDOT, is changed but that when a film used as a substrate material is allowed to stand for a long period of time at a temperature equal to or higher than the glass transition temperature of the film, the polymer chain of the substrate material may move and thus may be re-arranged thus changing the dimensions of the substrate film, and a low-molecular-weight component such as an oligomer or the like may transfer from the inside of the substrate material onto the surface thereof thus damaging the surface electrode layer. This phenomenon is referred to as a blooming-out phenomenon, which naturally occurs in almost all polymers.

The present invention adopted a method of applying a photocurable material which prevents the surface blooming-out of an oligomer occurring on the substrate film and additionally forms a network structure on both surfaces of the polymer, thus forming a photocoating film having a dense structure while preventing movement of the film at a temperature equal to or higher than the glass transition temperature of the polymer, thereby limiting the transfer of the oligomer.

Typically, a polymer such as polyester or polyacryl has a free volume of a non-cured state which is present between agglomerating polymer particles, and oligomers that do not participate in polymerization are transferred into such a space when heat or moisture is applied. As such, the oligomers may be transferred not by the unit of particles but by the unit of molecules at a temperature equal to or higher than a temperature which allows the movement of a material. Where such oligomers arrive at the other surface, a difference in polarity or cohesive force may occur, thus forming particles.

Specifically, to prevent the transfer of not the particles but the material, a much denser network structure is required. Thus, in the present invention a photocurable resin coating is used, and the thickness of the interposed coating layer is not limited because effects may be ascertained so long as the thickness is an extent that facilitates coating processing works. The density and the durability of the structure of the introduced photocurable coating layer are taken into consideration, and such a photocurable coating layer is effective at preventing the transfer of a material compared to a typical polymer in which curing is not introduced.

Also, where a photocurable layer is formed on both surfaces of the substrate, the deformation of the substrate may be effectively prevented even at a temperature equal to or higher than the glass transition temperature of the substrate and at a high relative humidity. Because of the introduction of the photocurable layer, it is difficult for moisture to permeate, and the photocurable layer applied on both surfaces of the substrate may protect the substrate from being deformed at a temperature equal to or higher than the glass transition temperature of the substrate.

As mentioned above, the present inventors adopted the method of forming the photocurable resin layer on both surfaces of the substrate film, thus preventing the surface electrode layer from being damaged due to the component such as an oligomer or the like that transfers from the inside of the film onto the surface thereof, as well as minimizing the dimensional deformation of the substrate material even upon aging at a temperature equal to or higher than the glass transition temperature of the substrate material.

In order to accomplish the above object, the present invention provides a transparent electrode film with an electrode layer, comprising a transparent substrate film; a photocurable hard coating layer formed on one surface or both surfaces of the substrate film; and a transparent conductive polymer electrode layer formed on the photocurable hard coating layer. The transparent conductive polymer electrode layer may be formed to a thickness of 40˜200 nm. When this layer is applied to a low thickness to the extent of about 40˜200 nm, the resultant transparent electrode film may be transparent to the level of light transmittance of about 87˜89% and a low surface resistance of about 200˜400 ohms/area.

In accordance with a preferred embodiment, as illustrated in FIG. 1, a photocurable resin layer having a degree of curing of 85% or more (hereinafter referred to as a fully cured surface or a fully cured layer) as a second layer is formed on one surface of a substrate film (a first layer), a photocurable resin layer having a degree of curing of 45˜85% (hereinafter referred to as a semi-cured surface or a semi-cured layer) as a third layer is formed on the other surface thereof, and an electrode layer (a fourth layer) containing PEDOT as an effective component is formed on the surface of the third layer.

### Advantageous Effects

According to the present invention, a transparent electrode film manufactured by forming an electrode layer containing PEDOT as an effective component on the surface of a substrate film is reliable because changes in surface resistance of the film are less than 10% compared to the initial resistance value even upon aging at a temperature equal to or higher than the glass transition temperature of the substrate film (e.g., in the case of a polyester film, 85° C.) and a high relative humidity (e.g. 85% RH), and also because there is almost no change in haze.

### DESCRIPTION OF DRAWING

FIG. 1 is a cross-sectional view illustrating the configuration of a transparent electrode film according to the present invention.

### MODE FOR INVENTION

The present invention provides a transparent electrode film using an electrode layer containing PEDOT as an effective component, in which changes in surface resistance are less than 10% compared to an initial resistance value even upon aging at a temperature equal to or higher than the glass transition temperature of a substrate material and a high relative humidity.

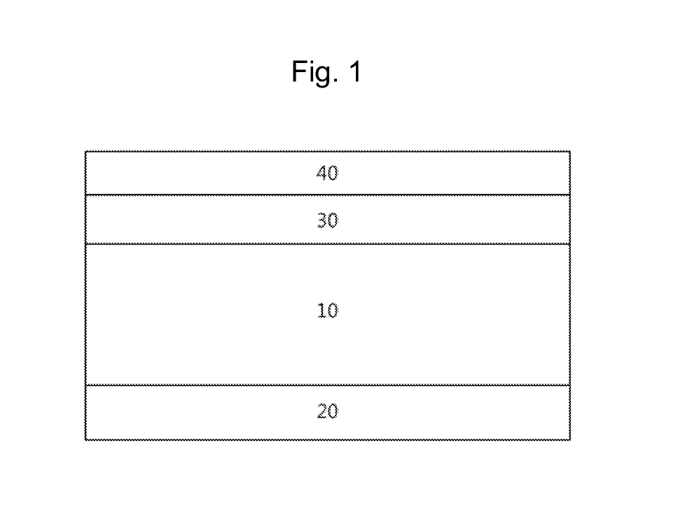

Below is a description of the transparent electrode film according to a preferred embodiment of the present invention with reference to FIG. 1.

A first layer is a substrate layer 10 of the transparent electrode film, and any transparent polymer may be used therefor. However, the use of a polyester film is preferable.

As a second layer and a third layer of the present invention, photocurable layers 20, 30 may be used, and any photocurable resin may be used therefor so long as it is of typical photocurable resin. Generally, there are exemplified a photocurable resin including a monomer, an oligomer or the like, a photocurable resin having one or more functional groups, and so on.

The photocurable layer 30 that is the third layer is a semi-cured layer, and may be formed using the same composition as in the photocurable layer 20 that is the second layer, and the degree of curing thereof may be controlled by adjusting the dose of irradiated light.

As such, the reason why the semi-cured layer or the semi-curing process is used is that, where the photocurable resin layer is semi-cured, stickiness that remains on the surface of the photocurable resin layer may be utilized. That is, this stickiness plays a role in enhancing adhesion to the electrode layer formed thereon. Thus, if curing is performed so that a degree of curing is 85% or more at which such stickiness disappears, the surface stickiness of the third layer may disappear, undesirably reducing the adhesion to the electrode layer formed thereon. In contrast, if the degree of curing is less than 45%, the adhesion to the conductive polymer electrode layer formed thereon may increase but stickiness may become excessive, and thus the corresponding layer may attach to the counter surface when wound into a roll, or the semi-cured layer is too soft, undesirably causing working problems when forming the conductive polymer electrode layer thereon.

The semi-cured layer that is the third layer may vary depending on the system of the component formed thereon. For example, when an organic conductive material dispersed in a solvent is formed, a photocurable material comprising a typical organic solvent-based photocurable resin composition may be used. However, when an electrode layer material dispersed in an aqueous solvent is formed, the photocurable resin composition may be used in a mixture with a photocurable resin having a polar group. For example, where the conductive polymer electrode layer 40 containing PEDOT as an effective component dispersed in the aqueous solvent is formed on the third layer, the photocurable resin for the third layer may be mixed with a photocurable resin having an oxide group, for example, acrylate having a methylene oxide group, acrylate having an ethylene oxide group, or acrylate having the other polar group, thus obtaining an electrode layer having superior adhesion.

As such, in the case where the acrylate having the polar group is mixed, it may be an oxide acrylate compound composed of an alkyl, an allyl, or a phenyl as a structure having one or more carbons, and the amount thereof should be 5˜80 parts by weight based on 100 parts by weight of the total acrylate resin. If the amount of the acrylate having the polar group is less than 5 parts by weight, the amount of polar acrylate is too low, undesirably deteriorating the adhesion between the semi-cured layer and the adhesive layer. In contrast, if the amount of polar acrylate is 80 parts by weight or more, the coating properties of the semi-cured layer may become too poor.

In the drawing, the conductive polymer electrode layer 40 is a transparent electrode layer. A conductive coating composition therefor may be prepared using PEDOT which is transparent and has high electrical conductivity as the conductive polymer. The preparation of the conductive coating composition using PEDOT is described below. Specifically, a predetermined amount of solvent is mixed with a PEDOT water-dispersion, a binder, a leveling agent and a solvent. The material for the coating layer composed mainly of a conductive polymer to form the transparent electrode layer of the present invention may include any conductive polymer which is able to form a transparent electrode layer, other than PEDOT. The component or amount of the coating composition may be applied similarly to the formation of an antistatic coating layer using a typical conductive polymer, and may be determined depending on the requirements such as electrical conductivity or surface resistance of an electrode layer. To obtain high conductivity, the amount of PEDOT may be increased, and to satisfy the other conditions such as bondability or coatability, the component and amount of the binder or the other additional surfactant adapted for the conditions may be applied as in the formation of the antistatic transparent conductive polymer electrode layer.

An electrode layer coating solution composition containing PEDOT as an effective component is applied on the surface of the third layer of the prepared film and dried, thus forming an electrode layer. The formation of this electrode layer may be performed using a variety of conventional processes for forming a coating layer on a film using a conductive polymer, including solution coating or vapor polymerization.

The binder which may be mixed with PEDOT of the present invention may include an organic binder having a functional group of a urethane, an acryl, an amide, an epoxy, an ester, an imide, an ether, etc., or an inorganic binder having a functional group of a silicate or a titanate, and the amount thereof may be appropriately set depending on the desired surface resistance value. Typically to reduce the surface resistance, the amount of the binder should be low.

The thickness of the conductive polymer electrode layer is regarded as important in terms of determining the surface resistance and light transmittance of the transparent electrode film. This layer should be applied as thin as possible, and preferably has a thickness of 40˜200 nm. If the thickness of the electrode layer is less than 40 nm, the electrode layer is too thin, undesirably making it difficult to form a uniform coating and deteriorating coating properties. In contrast, if the thickness of the electrode layer coating is 200 nm or more, the layer is too thick and surface resistance may be favorably remarkably decreased but the light transmittance of the film may become too low.

The substrate film represented as the substrate layer 10 in the present invention may be used without limitation so long as it is a polymer film that is usable as the substrate film of a touch screen panel. For example, a film comprising any one functional group selected from among an ester, a carbonate, an amide, an imide, an olefin, a sulfone, an ether, etc., a film comprising a polymer resulting from copolymerizing one or more functional groups, a film obtained by blending a polymer having one or more functional groups, or a laminate film obtained by stacking polymer films having different functional groups may be used.

The transparent electrode film according to the preferred embodiment of the present invention is illustrated in FIG. 1, and modifications thereof may be applied. For example, a fully photocured coating layer that is the second layer may be omitted. When the photocured coating layer that is the second layer is omitted in this way, mechanical properties may deteriorate. In addition, an antistatic coating layer rather than the electrode layer may be formed on the photocured coating layer that is the second layer of FIG. 1, thus forming a conductive polymer coating layer as in the electrode layer that is the fourth layer.

The aforementioned disclosure will be more specifically described via the following comparative examples and examples. However, the scope of the present invention is not construed as being limited to the examples, or is not limited to the polyester film used in the comparative examples and examples.

### COMPARATIVE EXAMPLE 1

A coating composition containing PEDOT as an effective component was applied on one surface of a commercially available polyester film having a thickness of 188 μm and then dried, thus forming a conductive polymer electrode layer having a coating thickness of 120 nm, resulting in a transparent electrode film, which was then manufactured into a touch cell. The touch cell thus manufactured had an X-axis terminal resistance of 290 ohms and a Y-axis terminal resistance of 596 ohms. The reason why the Y-axis terminal resistance is higher is that UV irradiation is carried out on the lower plate upon manufacturing the touch cell. Also, the haze value was 1.2%.

The coating solution for the electrode layer containing PEDOT as the effective component used in this comparative example was prepared as follows. Specifically, 34 g of a polythiophene conductive polymer solution, 60 g of ethylalcohol, 2 g of ethyleneglycol, 2 g of N-methyl-2-pyrrolidinone, 1.5 g of water-soluble urethane (based on 100% of solid content), and 0.5 g of a silicon-based additive were mixed.

This touch cell was placed in a constant temperature/humidity chamber at 85° C./85% RH, aged for 120 hr, taken out of the chamber, allowed to stand for about 8 hr, and dried, thus forming a module for evaluating aging properties.

The aging sample module, as above treated, had an X-axis terminal resistance of 435 ohms and a Y-axis terminal resistance of 572 ohms, and changes in surface resistance compared to the initial surface resistance value were about 50% in the case of the upper plate and −4% in the case of the lower plate, and the haze value was measured to be about 4.0%.

### COMPARATIVE EXAMPLE 2

Comparative Example 2 was performed in the same manner as in Comparative Example 1, with the exception that an intermediate layer comprising a thermosetting resin was formed on one surface of a polyester film having a thickness of 188 μm and an electrode layer was then formed thereon using a composition containing PEDOT as an effective component. As such, an X-axis terminal resistance was 266 ohms, and a Y-axis terminal resistance was 573 ohms. The haze of this sample was 1.18%.

The thermosetting composition for forming the intermediate layer of this comparative example was prepared by mixing 10 g of a urethane binder, 0.3 g of a curing agent, and 2 g of zirconium oxide (50 nm diameter, isopropyl alcohol 10% dispersion) with 30 g of an isopropyl alcohol solvent, and then applied on the surface of the polyester film, dried and cured to a dry thickness of 5 μm.

The touch cell manufactured as above was aged at 85° C./85% RH for 120 hr, after which changes in terminal resistance were determined, and for example, a change in X-axis terminal resistance was about 15%, and a change in Y-axis terminal resistance was −3.4%. In particular, in the case of this sample, the haze after aging was greatly increased to about 7%.

### COMPARATIVE EXAMPLE 3

This comparative example was performed in the same manner as in Comparative Example 1, with the exception that a photocurable resin layer was formed on one surface of a polyester film having a thickness of 188 μm and an electrode layer containing PEDOT as an effective component was then directly formed on the other surface thereof without forming a photocurable layer. As such, an X-axis terminal resistance of this sample was 275 ohms, and a Y-axis terminal resistance was 560 ohms.

The same aging testing was carried out, after which changes of the module were 40% in the case of the upper plate and −10% in the case of the lower plate. The haze value was measured to be 3.92%.

### EXAMPLE 1

A fully cured layer was formed on one surface of a polyester film having a thickness of 188 μm, and the same resin was applied on the other surface thereof and a dose of irradiated light was adjusted to obtain a degree of curing of 60%, thus forming a semi-cured layer.

The photocurable resin composition as above was prepared by mixing 10 g of a trifunctional acrylate monomer, 10 g of a trifunctional aliphatic acrylate oligomer, 10 g of a hexafunctional urethane acrylate oligomer, and 2 g of a 265 nm initiator with 68 g of ethyl acetate. The photocurable composition was dried to a coating thickness of 5 μm. Upon formation of the fully cured layer, the dose of irradiated UV light was 600 mJ/cm².

The surface of the semi-cured layer thus formed was coated with the PEDOT composition of Comparative Example 1 and then dried thus forming an electrode layer, and the other procedures were carried out in the same manner as in Comparative Example 1.

The touch cell manufactured as above had an X-axis terminal resistance of 275 ohms and a Y-axis terminal resistance of 570 ohms.

The adhesion of the electrode layer of the touch module manufactured as above was measured to be 5B according to ASTM D3359, which is evaluated to be good. The changes in terminal resistance after aging testing were 8.5% in the case of the upper plate and −5% in the case of the lower plate. The haze of this sample was measured to be 1.95%.

### EXAMPLE 2

Example 2 was performed in the same manner as in Example 1 with the exception that the degree of curing of the semi-cured layer was adjusted to 75%.

The touch cell manufactured as above had an X-axis terminal resistance of 265 ohms and a Y-axis terminal resistance of 587 ohms.

The adhesion of the electrode layer of the touch module manufactured as above was measured to be 5B according to ASTM D3359, which is evaluated to be good. The changes in terminal resistance after aging testing were 6.7% in the case of the upper plate and −6.5% in the case of the lower plate, and the haze value was measured to be 1.96%.

### COMPARATIVE EXAMPLE 4

Comparative Example 4 was performed in the same manner as in Example 1, with the exception that the degree of curing of the semi-cured layer was adjusted to 35%.

When the electrode layer containing PEDOT as an effective component was formed on the semi-cured layer using the transparent electrode film formed as above, the semi-cured layer was too soft, making it difficult to form the electrode layer.

### COMPARATIVE EXAMPLE 5

Comparative Example 5 was performed in the same manner as in Example 1, with the exception that the degree of curing of the semi-cured layer was adjusted to 90%.

In the manufacture of a touch cell using the above film, when the electrode layer composed of PEDOT was formed on the surface of the semi-cured layer, its wettability was poor and the adhesion was measured to be 1B according to ASTM D3359, from which the electrode layer was observed to be mostly stripped.

### EXAMPLE 3

Example 3 was performed in the same manner as in Example 1, with the exception that in the preparation of the photocurable resin composition for the semi-cured layer, an acrylate resin having an ethylene oxide group was mixed in an amount of 35 parts by weight based on the total weight of the photocurable resin composition of Example 1. An X-axis terminal resistance of this sample was 254 ohms and a Y-axis terminal resistance was 553 ohms.

The adhesion of the electrode layer of the touch module manufactured as above was measured to be 5B according to ASTM D3359, from which the adhesion of the electrode layer formed on the surface of the semi-cured layer is evaluated to be very good.

The changes in terminal resistance after aging testing were 5.7% in the case of the upper plate and −3% in the case of the lower plate, and the haze was measured to be 2.1%.

### EXAMPLE 4

Example 4 was performed in the same manner as in Example 3, with the exception that the degree of curing of the semi-cured layer was adjusted to 80%. An X-axis terminal resistance of this sample was 264 ohms and a Y-axis terminal resistance was 554 ohms.

The adhesion of the electrode layer of the transparent electrode film formed as above was measured to be 5B according to ASTM D3359, which is evaluated to be very good.

The changes in terminal resistance after aging testing were 7% in the case of the upper plate and −3.4% in the case of the lower plate, and the haze value was measured to be 1.87%.

As is apparent from the comparative examples and the examples, in the case of the PET film without surface treatment or of the substrate film the surface of which is treated with the thermosetting resin, the formation of the transparent electrode layer containing PEDOT as an effective component leads to changes in terminal resistance of a touch cell of 10% or more compared to the initial resistance value even after aging at 85° C./85% RH for 120 hr. In particular, changes in haze after aging are very large.

However, the photocurable resin layer that is fully cured is formed on one surface of the transparent substrate film such as polyester, the photocurable resin layer that is semi-cured is formed on the other surface thereof, and the electrode layer containing PEDOT as an effective component is formed on the surface of the semi-cured resin layer, so that changes in surface resistance after aging at 85° C./85% RH for 120 hr are less than 10% compared to the initial resistance value, and changes in haze after aging are not large, thereby obtaining a reliable transparent electrode film.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A transparent electrode film with an electrode layer, comprising:
a transparent substrate film;
a photocurable hard coating layer formed on one surface or both surfaces of the transparent substrate film; and
a transparent conductive polymer electrode layer formed on the photocurable hard coating layer.

2. The transparent electrode film of claim 1, wherein the photocurable hard coating layer at a position on which the transparent conductive polymer electrode layer is formed has a degree of curing of 45˜85%.

3. The transparent electrode film of claim 1, wherein the photocurable hard coating layer at a position on which the transparent conductive polymer electrode layer is not formed has a degree of curing of 85% or more.

4. The transparent electrode film of claim 1, wherein a conductive polymer of the electrode layer is poly(3,4-ethylenedioxythiophene).

5. The transparent electrode film of claim 1, wherein the photocurable hard coating layer is an acrylate-based photocurable resin layer.

6. The transparent electrode film of claim 5, wherein the acrylate-based photocurable resin layer is formed by mixing 5˜80 parts by weight of an oxide acrylate compound comprising an alkyl, an allyl, or a phenyl as a structure having one or more carbons, based on 100 parts by weight of a total acrylate resin.

7. The transparent electrode film of claim 2, wherein the photocurable hard coating layer at a position on which the transparent conductive polymer electrode layer is not formed has a degree of curing of 85% or more.

8. The transparent electrode film of claim 2, wherein a conductive polymer of the electrode layer is poly(3,4-ethylenedioxythiophene).

9. The transparent electrode film of claim 2, wherein the photocurable hard coating layer is an acrylate-based photocurable resin layer.

10. The transparent electrode film of claim 9, wherein the acrylate-based photocurable resin layer is formed by mixing 5˜80 parts by weight of an oxide acrylate compound comprising an alkyl, an allyl, or a phenyl as a structure having one or more carbons, based on 100 parts by weight of a total acrylate resin.

11. The transparent electrode film of claim 3, wherein a conductive polymer of the electrode layer is poly(3,4-ethylenedioxythiophene).

12. The transparent electrode film of claim 3, wherein the photocurable hard coating layer is an acrylate-based photocurable resin layer.

13. The transparent electrode film of claim 12, wherein the acrylate-based photocurable resin layer is formed by mixing 5˜80 parts by weight of an oxide acrylate compound comprising an alkyl, an allyl, or a phenyl as a structure having one or more carbons, based on 100 parts by weight of a total acrylate resin.

14. The transparent electrode film of claim 4, wherein the photocurable hard coating layer is an acrylate-based photocurable resin layer.

15. The transparent electrode film of claim 14, wherein the acrylate-based photocurable resin layer is formed by mixing 5˜80 parts by weight of an oxide acrylate compound comprising an alkyl, an allyl, or a phenyl as a structure having one or more carbons, based on 100 parts by weight of a total acrylate resin.
